(19) United States
(12) Patent Application Publication
(10) Pub. No.: US 2005/0252545 A1
(43) Pub. Date: Nov. 17, 2005

(54) INFRARED DETECTION OF SOLAR CELL DEFECTS UNDER FORWARD BIAS

(75) Inventors: Michael J. Nowlan, Arlington, MA (US); Scott B. Moore, Medway, MA (US); David C. Miller, Billerica, MA (US); Scot F. Sutherland, Tewksbury, MA (US)

Correspondence Address: NUTTER MCCLENNEN & FISH LLP, WORLD TRADE CENTER WEST, 155 SEAPORT BOULEVARD, BOSTON, MA, 02210-2604, US

(73) Assignee: SPIRE CORPORATION, Bedford, MA (US)

(21) Appl. No.: 10/709,529

(22) Filed: May 12, 2004

(51) Int. Cl. H01L 31/00

(52) U.S. Cl. 136/290

(57) ABSTRACT

Methods and apparatus are disclosed for detecting solar cell defects by applying a forward-biasing electric current through a silicon solar cell or a group of interconnected solar cells for a short duration and then analyzing the resulting thermal image of each cell with an infrared (IR) camera. The invention is particularly useful in assembling solar cell arrays or modules in which large numbers of cells are to be wired together. Automated module assemblers are disclosed in which the cells (or strings of cells) are tested for defects prior to final module assembly.

### STATEMENT REGARDING FEDERALLY SPONSORED RESEARCH OR DEVELOPMENT

The U.S. government has rights in this invention pursuant to contract awarded by the National Renewal Energy Laboratory, Contract No. ZDO-3-306628-12. This invention concerns solar cell arrays and, in particular testing of solar cells and solar cell subassemblies prior to fabrication of finished modules.

### BACKGROUND OF THE INVENTION

This invention concerns solar cell arrays and, in particular testing of solar cells and solar cell subassemblies prior to fabrication of finished modules.

Solar cell modules must not only convert sunlight into electrical current in an efficient manner but they must also be robust and durable enough to operate without servicing in remote or harsh environments. The need for highly reliable and weather resistant modules has lead to environmentally sealed constructions that require significant expense to assemble. Unfortunately, completed modules can sometimes fail, or operate in a sub-optimal manner, due to structural defects in one or more individual cells or in the wiring of such cells together. Often these faults are not detected until after encapsulation, when repair of defective cells is no longer possible.

There exists a need for better quality control during the steps that precede solar cell module finishing. Methods and apparatus that can detect defects in individual solar cells (or in strings of such cells) prior to final module assembly in a rapid or automated manner would satisfy a long-felt need in the art.

### BRIEF SUMMARY OF THE INVENTION

This invention discloses methods and apparatus for detecting solar cell defects by applying a forward-biasing electric current through a silicon solar cell or a group of interconnected solar cells for a short duration and then analyzing the resulting thermal image of each cell with an infrared (IR) camera. The invention is particularly useful in assembling solar cell arrays or modules in which large numbers of cells are to be wired together. Automated module assemblers are disclosed in which the cells (or strings of cells) are tested for defects prior to final module assembly.

The invention permits detection of defects such as microcracks, chipped cells, alignment errors and/or defective or missing solder joints, before module assembly and encapsulation. By providing quality assurance at this stage, the costs associated with assembly of non-functional (or low efficiency) modules can be avoided.

### BRIEF DESCRIPTION OF THE DRAWINGS

FIG. 1 is a schematic block diagram of an automated solar cell array production system according to the invention.

### DETAILED DESCRIPTION OF THE INVENTION

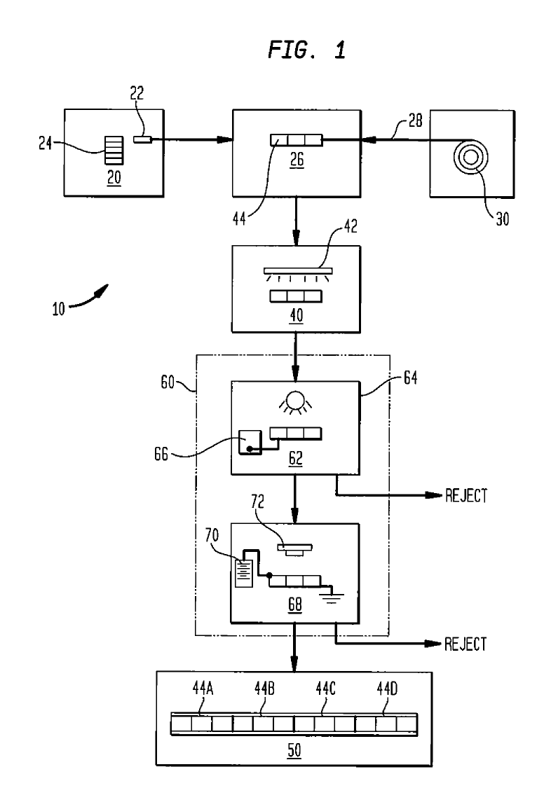

In FIG. 1 an automated solar cell module production system 10 interconnects solar cells 22 by soldering flat metal leads, or tabs, to cell contacts. The system 10 can process solar cells at a high-throughput, e.g., over 500 cells per hour, resulting in substantial cost savings in high volume production. In an initial cell alignment assembly 20, solar cells 22 are unloaded from stacks 24 and edge-aligned with a mechanical aligner 26. Tab material 28 is fed from reels 30, coated with flux, cut to length, and preferably provided with a stress-relief bend. Tabs 28 and cells 22 are aligned for soldering in a solder head assembly 40. High-intensity lamps 42 in the solder head assembly 40 provide radiant thermal energy to the cell and tabs. Both front and back cell contacts can be soldered in a single heating step to form a solar cell string 44.

A variety of solar cell sizes and shapes can be processed. The number of cells per string, the number of strings per module, and the string orientation in the module are software programmable. Each completed string is ready for further processing by a module assembler 50.

However, prior to module assembly, the solar cells strings are tested in accordance with the present invention by test assembly 60. The test unit 60 can include a photoelectric test station 62. In one preferred embodiment of the photoelectric tester 62, a pulsed xenon lamp 64 illuminates the cell string, and an I-V curve is measured via electronic load and meter 66. Strings that fail the photoelectric response test are placed in a reject bin.

In a second defect-detection station 68, structural defects are detected by applying a forward-bias current to the string with a current source 70 to cause heating. In one embodiment, the forward-bias current density through one or more cells can range from about 70 mA/cm² to about 200 mA/cm². The cells are then thermally imaged, e.g., with an infrared CCD camera 72. Defects such as microcracks, chipped cells, alignment errors and/or defective or missing solder joints can be detected by discontinuities in the thermal image.

In one preferred embodiment, the inspecting step includes a comparison of the thermal image of a solar cell under inspection with a corresponding thermal image of a reference cell. The image analysis can employ, for example, an edge detection technique to detect microcracks, chips and the like. In this technique, detected edges can be compared with a known or model cell geometry to detect features that deviate from model cell parameters. Alternatively, the image analysis can be based on intensity variance measurements, in which non-uniformities are indicative of defects. Image analysis can be conducted with or without comparison to reference values. Based on this image analysis, the strings are again placed either in a reject bin or in the proper location for further assembly of the strings into modules in the module assembler 50.

In the module assembler 50, the module circuit design specifies the number of cells connected in series, the number of cells connected in parallel, and the frequency of parallel interconnects. The number of cells in series determines the module operating voltage. The cell area and the number of cells in parallel are proportional to the module current output. The assembled module is then encapsulated.

For example, the finished module can consist of interconnected and encapsulated solar cells in a durable and environmentally protected package. Tempered low-iron glass is normally used for the front cover (or superstrate) to provide permanently transparent protection for the optical surface of the module. However, other types of glass, such as window glass, may be used. The remainder of the laminate can consist of clear ethylene vinyl acetate (EVA) encapsulant, the cell circuit, a second layer of EVA, a fiberglass sheet, and a back cover film.

It should be appreciated that the techniques described above can be practiced in both fully-automated and batch-mode inspection processes. These techniques can be integrated with string assembly, as described, or they can be done as a stand alone operation. It should also be apparent that the techniques for testing of solar cell strings can be applied equally to the testing of individual cells. One advantage of performing thermal imaging after string assembly is that both structure faults in the individual cells and wiring defects in the strings can be determined at the same time before the more significant expense of module finishing and encapsulation is carried out.

Background information and further details on assembly of solar cell modules can be found in a report published by the National Renewal Energy Laboratory entitled “Automated Solar Cell Assembly Teamed Process Research” Pub. No. NREL/TP-411-20794 (February 1996), incorporated herein in its entirety by reference.

Those having ordinary skill in the art will appreciate that various modifications can be made to the above embodiments without departing from the scope of the invention.

1. A system for inspecting solar cell arrays, comprising
at least one module for assembling a solar cell array, and
at least one test module for inspecting said array, said inspection module comprising
an electrical source adapted for electrically coupling to said solar cell array so as to generate a forward-bias current through said array in order to cause its heating, and
an infrared camera directed at said heated cell to generate thermal images of at least a portion of the array.

2. The system of claim 1, further comprising an image analysis module receiving said thermal image, and inspecting said image so as to identify defects in the solar cell array.

3. The system of claim 1, wherein said defects comprise any of microcracks, defective or missing solder joints.

4. The system of claim 1, wherein said defects occur at interconnections among cells forming said array.

5. The system of claim 4, wherein said defects comprise any of defective solder, weld or adhesive bonds between any two of the cells in said array.

6. The system of claim 2, wherein said image analysis module employs an edge detection technique to identify defects in said thermal image.

7. The system of claim 2, wherein said image analysis module employs an intensity variance technique to identify defects in said thermal image.

8. The system of claim 1, wherein the density of the forward-bias current ranges from about 70 mA/cm² to about 200 mA/cm².

9. The system of claim 1, wherein said solar cell array comprises a plurality of solar cells each formed of a monocrystalline or polycrystalline semiconductor material.

10. The system of claim 1 wherein the system further comprises an automated conveyance element for transporting array components to the inspection module prior to finishing the array.

11. A method for detecting defects in a solar cell, comprising
generating a forward-bias current through the cell to cause its heating, and
inspecting a thermal image of said heated cell to identify defects therein.

12. The method of claim 11, further comprising obtaining a thermal image of the heated cell in the infrared region of the electromagnetic spectrum.

13. The method of claim 11, wherein said inspecting step comprises identifying defects that disrupt a normal flow of said current through the cell.

14. The method of claim 13, wherein said defects comprise any of microcracks or missing solder joints.

15. The method of claim 11, wherein said inspecting step comprises comparing the thermal image of a solar cell under inspection with a corresponding thermal image of a reference cell.

16. The method of claim 11, further comprising applying an edge detection technique to said thermal image to identify said defects.

17. The method of claim 11 wherein the method is practiced in an automated array assembler.

18. The method of claim 17 where in the inspection step occurs prior to finishing the array.

19. The method of claim 17 where in the inspection step occurs prior to encapsulation of the array.
